(19) United States
(12) Patent Application Publication
(10) Pub. No.: US 2002/0076621 A1
(43) Pub. Date: Jun. 20, 2002

(54) LOCALIZED PARTIAL COHERENCE CONTROL

(76) Inventors: REBECCA D. MIH, WAPPINGERS FALLS, NY (US); KEVIN S. PETRARCA, NEWBURGH, NY (US); DONALD C. WHEELER, BEDFORD HILLS, NY (US)

Correspondence Address: TIFFANY L. TOWNSEND, IBM CORPORATION, INTELLECTUAL PROPERTY LAW, BLDG. 300-482, 2070 ROUTE 52, HOPEWELL JUNCTION, NY, 12533-6531, US

(21) Appl. No.: 09/469,920

(22) Filed: Dec. 22, 1999

(51) Int. Cl. G03F 9/00

(52) U.S. Cl. 430/5

(57) ABSTRACT

A photolithographic mask having a primary photolithographic mask having a pattern thereon, the pattern comprising at least two portions, each portion requiring an individual optimal energy to image the pattern, each optimal energy of each portion dissimilar to at least one of the at least two portions and a secondary photolithographic mask on at least one portion of the primary mask, the secondary mask capable of attenuating the light on at least one of the at least two portions such that the optimal energy required to image the pattern on the at least one portion is similar to another of the at least two portions.

### RELATED APPLICATIONS

This application is related to copending U.S. Application Ser. No. 09/ , filed on Dec. 22, 1999, entitled “Controlled Annular Illumination”, assigned to the present assignee and which is incorporated by reference in its entirety.

### FIELD OF THE INVENTION

This invention is directed to the field of photolithographical processing of semiconductor features and more particularly to methods of improving illumination to distinct portions of a mask or reticle.

### BACKGROUND OF THE INVENTION

Lithography refers to a family of techniques for transferring an image rendered on one form of media onto that of another media, typically by photographically “printing” the image. Obvious examples are posters and postage stamps. Similarly, semiconductor microcircuit have been made, for many years, using this technique: silicon substrates upon which these circuits are to be created are coated with a light (radiation) sensitive material chosen for its ability to accurately replicate the desired image, exposed to a source of radiation partially blocked by a mask to render a pattern. Typically, the circuit pattern is rendered as a positive or negative mask image which is then “projected” onto the coated substrate, in either a transmission or reflection mode, depending on the type of optical system being used. The mask is thus imaged on the surface of the coated substrate where the incoming light (radiation) chemically changes those areas of the coating on which the process light (radiation) impinges, usually by polymerizing the coating exposed to the radiation. Depending on the developer (solvent) used the unpolymerized areas are removed, being more soluble in the developer than the polymerized regions, and the desired pattern image remains.

Since this process allows the user to effectively replicate the mask image indefinitely with little additional expense, “projection” lithography has become an essential and powerful tool for manufacturing semiconductor “chips.” However, as the drive to place ever greater numbers of components on those chips continues, the need to resolve ever smaller features also continues. In doing so, the diffraction limits of visible light wavelengths have been reached. Currently “deep” ultraviolet and “soft” x-radiation (wavelengths from about 300nm to 60 nm) are now being actively researched. However, the problem of diffraction limited optics remains and the drive to using wavelengths below 300 nm provide only limited advantage.

It is known that by introducing partial coherence into the illumination affects the image quality of printed features, that is, partial coherence can counter attenuation. Providing a source of partially coherent illumination is normally accomplished by underfilling the optical system entrance pupil with Kohler illumination. In other words, the source is imaged into the entrance pupil and this image is smaller than the pupil by a factor of about σ=0.6. This value of σ is a reasonable compromise in order to achieve the desired balance between attenuation of small features and “ringing” in all features. Factors in the range of 0.2<=σ<=0.8 could be used as well.

Chip manufacturers have also begun using “engineered illumination” to help print smaller and smaller features. This technique relies upon the use of various “patterns” of illumination including the “under-filled” Kohler disk, quadrapole illumination, and off-axis illumination. Unfortunately, in order to use one or several of these methods, results in reduced condenser efficiency or requires that the illuminator be seriously modified. For example, when a somewhat higher coherence is needed, an aperture is partially closed which reduces efficiency.

Off-axis illumination requires that the condenser be disassembled and reconfigured. All of these methods are time consuming, expensive, and less efficient then current technology albeit capable of achieving smaller design patterns. Finally, the ability to provide a source of illumination which is not only bright but optimized for the features sizes exhibited by the part pattern to be replicated is critical.

### SUMMARY OF THE INVENTION

It is an object of the present invention to provide a mask capable of optimizing the light needed for different portions of a pattern.

It is also an object of the present invention to provide a mask capable of attenuating light to the object below.

It is a further object of the present invention to provide a mask that can be customized with an attenuating substance.

In accordance with the above listed and other objects we provide a photolithographic mask comprising:

a primary photolithographic mask having a pattern thereon, the pattern comprising at least two portions, each portion requiring an individual optimal energy to image the pattern, each optimal energy of each portion dissimilar to at least one of the at least two portions;

a secondary photolithographic mask on at least one portion of the primary mask, the secondary mask capable of attenuating the light on at least one of the at least two portions such that the optimal energy required to image the pattern on the at least one portion is similar to another of the at least two portions.

### BRIEF DESCRIPTION OF THE DRAWINGS

These and other features, aspects, and advantages will be more readily apparent and better understood from the following detailed description of the invention, in which:

FIG. 1 is a cross sectional view showing the geometry of the attenuating material of the instant invention.

### BRIEF DESCRIPTION OF THE PREFERRED EMBODIMENTS

When a semiconductor substrate is being processed, many layers, or levels, are deposited. Each of those levels has to communicate with the levels above and below it. Therefore, each level has an individual specific configuration that allows it to perform its own function and to communicate between the levels above and below. Since the configuration of any individual level is different, the concentration of features can vary both from level to level and at different locations within the same level. Examples of features include, but are not limited to, lines, vias and transistor gates. When the concentrations of features varies within a single level, the process of forming the features can be more complex. For example, where lines are within close proximity, nested, the optimal processing parameters can be different than locations where the lines are distant isolated, causing a processing proximity effect. Of course the determination of what is close and what is distant is relative. Generally, nested lines are lines where the space between the lines, s, is less than or equal to twice the width of the lines, 1, itself, s ≦2* 1 and isolated lines are lines where the space between the lines is three times the width of the lines, s≦3* 1. However, it is accepted in the art that when features are formed using photolithography that spacing variations between features on the same level can effect the efficiency of photolithography techniques. The invention would enable the end user to use one illumination to more effectively image both isolated and nested features.

In the instant invention, a method and apparatus for minimizing the processing proximity effect locally, on the mask itself, has been developed. A mask can be comprised of a number of materials but for purposes of illustration we will presume that the mask is a reticle comprised of any suitable material known in the art. The invention utilizes light attenuation properties and alters the surface of the reticle such that the available light to different regions of the semiconductor layer is variable.

In a first embodiment of the instant invention, a substance which attenuates light is deposited on a photomask. The substance is then patterned as desired by the end user. Alternatively, the substance could be deposited in such a way that the pattern is laid during the deposition. Further, it is not necessary in the instant invention that the substance be patterned at all. In this first embodiment the patterned substance would be present in the regions of the substrate where the patterning planned on the mask for that level will produce features that are isolated. As stated earlier the determination of nested and isolated are relative. For purposes of illustration only, we will consider “nested” and “isolated” features to be groupings of features on the same level with similar imaging properties. For example, when features are nested, within s ≦2* 1 of each other, the amount of light necessary to image those features is similar and they would form one grouping. When features are not within s ≦2* 1, and most probably s >31, are isolated, the amount of light, the illumination, necessary to image those features is similar but may be different from the illumination necessary to image features that are nested.

When the reticle is treated such that different regions have different illuminations the refractive properties of the treated regions will be different. Where the refractive properties are different the ability of the reticle to image in the region will be different since refractive properties are one of the variables that effect imaging. There are other variables that effect imaging and they may be modified directly or indirectly when the refractive properties are effected. The purpose of the treatment, applying a substance which attenuates light to the surface of the reticle, is to deliver to the substrate level being formed a more optimal amount of light necessary to form all features regardless of their location and proximity to other features. To accomplish the attenuation, the substance should be of the nature that selectively absorbs light as a function of the angle of incidence. The material should have a cylindrical grain structure and the long axis of the grains should be oriented normal to the surface of the reticle. Examples of suitable substance material include amorphous silicon, porous silicon, amorphous carbon, buckninster fullerenes and colloidal composites. Each grain in the substance is surrounded by a “grain boundary”. The grain boundary can be defined as the region or interface that exists between the grains. Typically, the grain boundary is less dense than the individual grains.

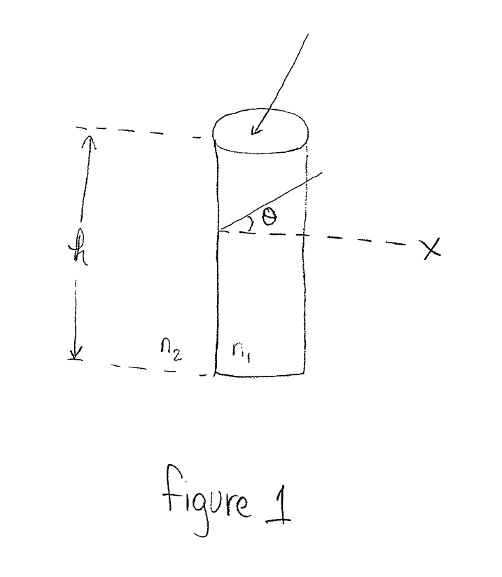

Any given ray of light has an associated energy. The energy associated with a ray of light can be affected by the reflective properties of the object “subjected to” the light. In the instant case, a portion of the light's energy enters the pipe and part is reflected. The part initially reflected does not transmit and does not effect the imaging of the surface below. The part of the light that enters the light pipe enters at an angle. The angle θ, is defined as the angle that the light ray deviates from the normal, x, of the pipe's wall, as shown in FIG. 1. Each material which forms a light pipe has an associated critical angle, θ_{c}. θ_{c} is a function of the index of refractions for the material comprising the light pipe and the material surrounding the material comprising the light pipe. Specifically, sin θ_{c}=(n₂/n₁), where n₂ is the index of refraction of the material outside of the light pipe, for example at the boundary between the grains forming the individual cylindrical grains of the light pipes and n₁ is the index of refraction of the light pipe material. For example, if the grain boundary, n2 is-air, which has a refractive index of 1 and the grain, n1 is glass which has a refractive index of 1.5, then θc=arcsin (n2/nl). θc would therefore be 41.8°. Each θ associated with an incident ray of light is necessarily either less than θc or greater than or equal to θc. Where θ is greater than or equal to θc, total internal reflection occurs. Where θ is less than θ_{C} a portion of the light is refracted and exits the light pipe boundary and enters the grain boundary region and is scattered and absorbed. It can be seen then that the light exiting the light pipes is attenuated, that is has a different energy, preferably less energy, than the initial incident light. The number of reflections, N, is dependent on the height of the light pipe, which is the thickness of the substance deposited. The number of reflections, N, can be represented by the equation

$$N = ( int ( \frac{h}{2 r * tan θ} ) + 1 )$$

where N is the number of reflections internal to the light pipe, h is the height of the light pipe, r is the radius of the pipe and θ is the angle of incidence measured from the normal of the pipe's sidewalls and int is the integer function.

By virtue of the fact that light rays traveling at less than θ_{C} are attenuated at each ref lection/refraction, we can selectively decrease the energy of the collection of rays. We can therefore, control the amount of attenuation by varying a number of factors. An end user can adjust the height of the light pipe and the thickness of the deposited attenuating material. An end user can also vary r, the radius of the cylindrical grain. Additionally, the selection of n₂ and n₁ can be engineered to change the critical angle for total internal reflection. Also, the ratio of the grain boundary to grain volume can be altered by reengineering the grain size and therefore the radius of the grain with respect to the grain boundary.

The amount of attenuation with each reflection could be determined by the end user according to Maxwell's equation. If there are no restraints on the height of the material deposited then the height of the material could be determined based on the information given by solving Maxwell's equation. For example, if 12% of all light is refracted at each reflection and the end user needs 41% of the incident light then he can determine that he needs 7 refractions. Once the number of refractions, N, is known then the height of the attenuating material can be determined. If for example N=30 and θ=40° and the radius of the material is 100Å, then the height of the material is 5000Å. If there is a height restraint for the material and 5000Å is too thick then the end user choose a material with a different radius or adjust the incident angle.

While the invention has been described in terms of specific embodiments, it is evident in view of the foregoing description that numerous alternative, modifications and variations will be apparent to those skilled in the art. Thus, the invention is intended to encompass all such alternatives, modifications and variations which fall within the scope and spirit of the invention and the appended claims.

What is claimed:

1. A photolithographic mask comprising:
a primary photolithographic mask having a pattern thereon, the pattern comprising at least two portions, each portion requiring an individual optimal energy to image the pattern, each optimal energy of each portion dissimilar to at least one of the at least two portions;
a secondary photolithographic mask on at least one portion of the primary mask, the secondary mask capable of attenuating the light on at least one of the at least two portions such that the optimal energy required to image the pattern on the at least one portion is similar to another of the at least two portions.

2. The photolithographic mask according to claim 1 wherein the secondary mask is patterned prior to being on the primary mask.

3. The photolithographic mask according to claim 1 wherein the secondary mask is patterned after being on the primary mask.

4. The photolithographic mask according to claim 1 wherein the secondary mask comprises a material selected from the group consisting of amorphous silicon, porous silicon, amorphous carbon, buckminster fullerenes and colloidal composites.

5. The photolithographic mask according to claim 4 wherein the secondary mask comprises buckminster fullerenes.

6. The photolithographic mask according to claim 4 wherein the secondary mask comprises amorphous silicon.

7. The photolithographic mask according to claim 1 wherein each of the at least two portions comprise features.

8. The photolithographic mask according to claim 7 wherein one of the at least two portions comprises nested features and the other of the at least two portions comprises isolated features.
